(19) United States
(12) Patent Application Publication
(10) Pub. No.: US 2024/0079427 A1
(43) Pub. Date: Mar. 7, 2024

(54) IMAGING APPARATUS AND MANUFACTURING METHOD OF IMAGING APPARATUS

(71) Applicant: SONY SEMICONDUCTOR SOLUTIONS CORPORATION, Kanagawa (JP)

(72) Inventor: Kei FUKUHARA, Kanagawa (JP)

(73) Assignee: SONY SEMICONDUCTOR SOLUTIONS CORPORATION, Kanagawa (JP)

(21) Appl. No.: 18/256,179

(22) PCT Filed: Nov. 11, 2021
(86) PCT No.: PCT/JP2021/041450

§ 371 Date: Jun. 6, 2023

(30) Foreign Application Priority Data
Dec. 16, 2020 (JP) 2020-208602

(51) Int. Cl. H01L 27/146

(52) U.S. Cl. CPC H01L 27/14621; H01L 27/14623; H01L 27/14645; H01L 27/14685

(57) ABSTRACT

Provided is an imaging apparatus capable of enhancing heat resistance of a color filter and a manufacturing method of the imaging apparatus. An imaging apparatus includes a semiconductor substrate, a color filter provided on one surface side of the semiconductor substrate, and a first sealing material provided on the one surface side, the first sealing material that covers the color filter. The first sealing material includes a material capable of transmitting light of a wavelength band set in advance and having a thermal conductivity of 0.5 W/m·K or less.

### TECHNICAL FIELD

The present disclosure relates to an imaging apparatus and a manufacturing method of an imaging apparatus.

### BACKGROUND ART

Patent Document 1 discloses forming a transfer lens including a transparent resin layer on a color filter.

### CITATION LIST

### Patent Document

Patent Document 1: Japanese Patent Application Laid-Open No. 2006-41467

### SUMMARY OF THE INVENTION

### Problems to be Solved by the Invention

In an imaging apparatus, it is desired to enhance heat resistance of a color filter so that heat treatment at high temperature may be performed even after the color filter is formed.

The present disclosure has been achieved in view of such circumstances, and an object thereof is to provide an imaging apparatus capable of enhancing heat resistance of a color filter and a manufacturing method of the imaging apparatus.

### Solutions to Problems

An imaging apparatus according to an aspect of the present disclosure includes a semiconductor substrate, a color filter provided on one surface side of the semiconductor substrate, and a first sealing material provided on the one surface side, the first sealing material that covers the color filter. The first sealing material includes a material capable of transmitting light of a wavelength band set in advance and having a thermal conductivity of 0.5 W/m·K or less.

With this arrangement, since the color filter is covered with the first sealing material, the first sealing material suppresses thermal conduction to the color filter even in a case where heat treatment at high temperature (for example, 250° C. or higher) is performed after the first sealing material is formed. Since the first sealing material 51 protects the color filter from the heat treatment at high temperature, heat resistance of the color filter may be enhanced.

A manufacturing method of an imaging apparatus according an aspect of the present disclosure includes steps of forming a color filter on one surface side of a semiconductor substrate, forming a first sealing material on the one surface side and covering the color filter, and performing heat treatment on an entire substrate including the semiconductor substrate, the color filter, and the first sealing material after forming the first sealing material. A material capable of transmitting light of a wavelength band set in advance and having a thermal conductivity of 0.5 W/m·K or less is used as the first sealing material.

With this arrangement, the first sealing material suppresses the thermal conduction to the color filter even in a case where the heat treatment at high temperature (for example, 250° C. or higher) is performed after the first sealing material is formed. Since the first sealing material protects the color filter from the heat treatment at high temperature, heat resistance of the color filter may be enhanced.

### BRIEF DESCRIPTION OF DRAWINGS

FIG. 1 is a diagram illustrating a configuration example of an imaging apparatus according to an embodiment of the present disclosure.

FIG. 2 is a cross-sectional view illustrating a part of the imaging apparatus according to the embodiment of the present disclosure, a configuration example of a pixel region.

FIG. 3 is a cross-sectional view illustrating a configuration example 1 of the pixel region according to the embodiment of the present disclosure.

FIG. 4 is a cross-sectional view illustrating a configuration example 2 of the pixel region according to the embodiment of the present disclosure.

FIG. 5 is a cross-sectional view illustrating a configuration example 3 of the pixel region according to the embodiment of the present disclosure.

FIG. 6 is a cross-sectional view illustrating a configuration example 4 of the pixel region according to the embodiment of the present disclosure.

FIG. 7 is a plan view illustrating a configuration example 5 of the pixel region according to the embodiment of the present disclosure.

FIG. 8 is a cross-sectional view illustrating the configuration example 5 of the pixel region according to the embodiment of the present disclosure.

FIG. 9 is a cross-sectional view illustrating a configuration example 6 of the pixel region according to the embodiment of the present disclosure.

FIG. 10 is a cross-sectional view illustrating a configuration example 7 of the pixel region according to the embodiment of the present disclosure.

FIG. 11 is a cross-sectional view illustrating a configuration example 8 of the pixel region according to the embodiment of the present disclosure.

FIG. 12 is a cross-sectional view illustrating a manufacturing method_example 1 of the imaging apparatus according to the embodiment of the present disclosure.

FIG. 13 is a cross-sectional view illustrating a manufacturing method_example 2 of the imaging apparatus according to the embodiment of the present disclosure.

FIG. 14 is a cross-sectional view illustrating a manufacturing method_example 3 of the imaging apparatus according to the embodiment of the present disclosure.

FIG. 15 is a cross-sectional view illustrating a manufacturing method_example 4 of the imaging apparatus according to the embodiment of the present disclosure.

FIG. 16 is a block diagram illustrating a configuration example of an imaging apparatus according to the embodiment of the present disclosure.

FIG. 17 is a view depicting an example of a schematic configuration of an endoscopic surgery system.

FIG. 18 is a block diagram depicting an example of a functional configuration of a camera head and a CCU.

FIG. 19 is a block diagram depicting an example of schematic configuration of a vehicle control system.

FIG. 20 is a diagram depicting an example of an installation position of an outside-vehicle information detecting unit and an imaging section.

### MODE FOR CARRYING OUT THE INVENTION

Hereinafter, an embodiment of the present disclosure is described with reference to the drawings. In the illustration of the drawings referred to in the following description, the same or similar portions are denoted by the same or similar reference signs. It should be noted that the drawings are schematic, and a relationship between a thickness and a planar dimension, a ratio of the thicknesses between layers and the like are different from actual ones. Therefore, specific thicknesses and dimensions should be determined in consideration of the following description. Furthermore, it goes without saying that dimensional relationships and ratios are partly different between the drawings.

Definition of directions such as upward and downward directions in the following description is merely the definition for convenience of description, and does not limit the technical idea of the present disclosure. For example, it goes without saying that if a target is observed while being rotated by 90°, the upward and downward directions are read as rightward and leftward directions, and if the target is observed while being rotated by 180°, the upward and downward directions are inverted.

<Configuration Example of Imaging Apparatus>

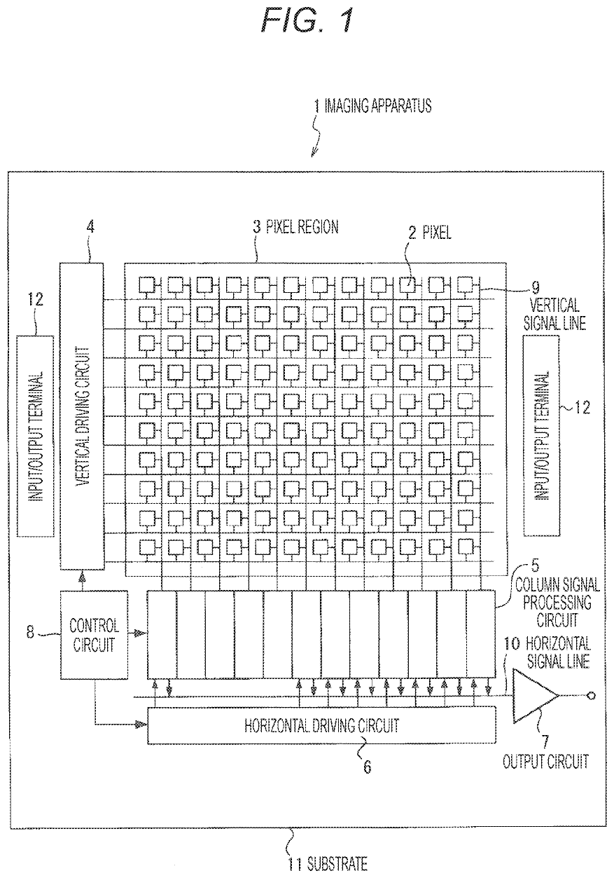

FIG. 1 is a diagram illustrating a configuration example of an imaging apparatus 1 according to an embodiment of the present disclosure. As illustrated in FIG. 1, the imaging apparatus 1 includes a semiconductor substrate 11 (for example, a silicon substrate), and a pixel region (a so-called imaging region) 3 and a peripheral circuit unit formed on the semiconductor substrate 11.

The pixel region 3 is a region in which pixels 2 including a plurality of photoelectric conversion elements (for example, photodiodes) is regularly arrayed two-dimensionally. The pixel 2 includes a photodiode and a plurality of pixel transistors (so-called MOS transistors). The plurality of pixel transistors may include three transistors, which are a transfer transistor, a reset transistor, and an amplification transistor, for example. The plurality of pixel transistors may include four transistors by adding a selection transistor to the above-described three transistors. Since an equivalent circuit of a unit pixel is similar to a normal one, the detailed description thereof is omitted. The pixel 2 may also have a shared pixel structure. The shared pixel structure includes a plurality of photodiodes, a plurality of transfer transistors, one shared floating diffusion, and other shared pixel transistors one for each type.

The peripheral circuit unit includes a vertical driving circuit 4, a column signal processing circuit 5, a horizontal driving circuit 6, an output circuit 7, a control circuit 8 and the like.

The control circuit 8 receives an input clock and data giving a command of an operation mode and the like, and outputs data of internal information and the like of a solid-state imaging device. That is, the control circuit 8 generates a clock signal and a control signal that serve as a reference for operation of the vertical driving circuit 4, the column signal processing circuit 5, the horizontal driving circuit 6 and the like on the basis of a vertical synchronization signal, a horizontal synchronization signal, and a master clock. Then, the control circuit 8 inputs the signals to the vertical driving circuit 4, the column signal processing circuit 5, the horizontal driving circuit 6 and the like.

The vertical driving circuit 4 including a shift register, for example, selects pixel driving wiring, supplies a pulse for driving the pixel to the selected pixel driving wiring, and drives the pixels in a row unit. That is, the vertical driving circuit 4 sequentially selects to scan the pixels 2 in the pixel region 3 row by row in a vertical direction and supplies a pixel signal based on a signal charge generated according to a light receiving amount by the photodiode of each pixel 2 to the column signal processing circuit 5 through a vertical signal line 9.

The column signal processing circuits 5 arranged for respective columns of the pixels 2 perform signal processing such as noise removal on the signals output from the pixels 2 of one row for each pixel column. That is, the column signal processing circuit 5 performs signal processing such as CDS for removing fixed pattern noise unique to the pixel 2, signal amplification, and AD conversion. A horizontal selection switch (not illustrated) is provided so as to be connected to a horizontal signal line 10 on an output stage of the column signal processing circuit 5.

The horizontal driving circuit 6 including a shift register, for example, selects each of the column signal processing circuits 5 in turn by sequentially outputting horizontal scanning pulses and allows each of the column signal processing circuits 5 to output the pixel signal to the horizontal signal line 10.

The output circuit 7 performs signal processing on the signals sequentially supplied from the respective column signal processing circuits 5 through the horizontal signal line 10 to output. For example, there is a case where the output circuit 7 merely buffers, or a case where this performs black level adjustment, column variation correction, various types of digital signal processing and the like. An input/output terminal 12 communicates signals with the outside.

<Configuration Example of Pixel Region>

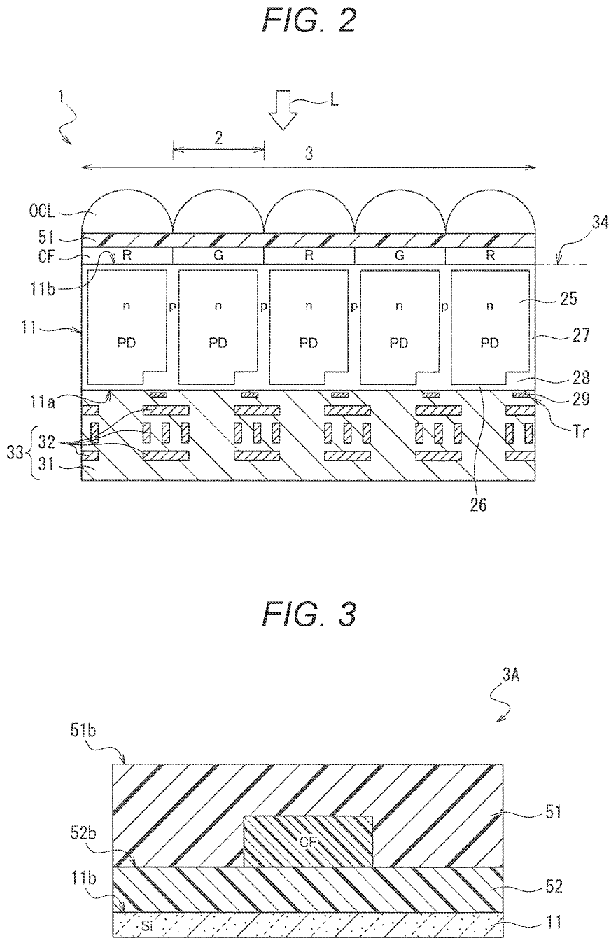

FIG. 2 is a cross-sectional view illustrating a part of the imaging apparatus 1 according to the embodiment of the present disclosure, a configuration example of the pixel region 3. The imaging apparatus 1 is a backside irradiation type CMOS image sensor, for example. In the imaging apparatus 1, the pixel 2 includes a photodiode PD and a plurality of pixel transistors Tr. The photodiode PD is formed over an entire region in a thickness direction of the semiconductor substrate 11, and is formed as, for example, a pn junction type photodiode including an n-type semiconductor region 25 and a p-type semiconductor region 26. The p-type semiconductor region 26 also serves as a hole charge accumulation region for suppressing a dark current.

Each pixel 2 including the photodiode PD and the pixel transistor Tr is separated by an element separation region 27. The element separation region 27 is formed by, for example, a p-type semiconductor region and is grounded. The pixel transistor Tr is formed by forming n-type source region and drain region not illustrated in a p-type semiconductor well region 28 formed on a front surface 11a side of the semiconductor substrate 11, and forming a gate electrode 29 on a substrate front surface between the respective regions via a gate insulating film. In the drawing, a plurality of pixel transistors is represented by one pixel transistor Tr and schematically represented by the gate electrode 29.

A multilayer wiring layer 33 is formed on the front surface 11a side of the semiconductor substrate 11. The multilayer wiring layer 33 includes wiring 32 of a plurality of layers arranged in multiple layers via an interlayer insulating film 31. The imaging apparatus 1 is a backside irradiation type, and light is not incident on a side of the multilayer wiring layer 33 (that is, the front surface side). Therefore, a layout of the wiring 32 may be freely set.

In the semiconductor substrate 11, a color filter CF and an on-chip microlens OCL are provided on a back surface 11b side serving as a light receiving surface 34 of the photodiode PD. Furthermore, a first sealing material 51 is provided between the color filter CF and the on-chip microlens OCL so as to cover at least a part of the color filter CF. Furthermore, although not illustrated in FIG. 2, a second sealing material 52 (refer to FIG. 3) may be provided between the color filter CF and the semiconductor substrate 11. Materials forming the first sealing material 51 and the second sealing material 52 will be described later.

The on-chip microlens OCL is formed using, for example, an organic material such as a resin. As a color filter 42, for example, a Bayer array color filter is used. Light L is incident on the back surface 11b side of the semiconductor substrate 11. The light L includes, for example, visible light. Furthermore, the light L may include infrared light in addition to the visible light. The light L is condensed by the on-chip microlens OCL, transmitted through the first sealing material 51 and the color filter CF, and enters each photodiode PD.

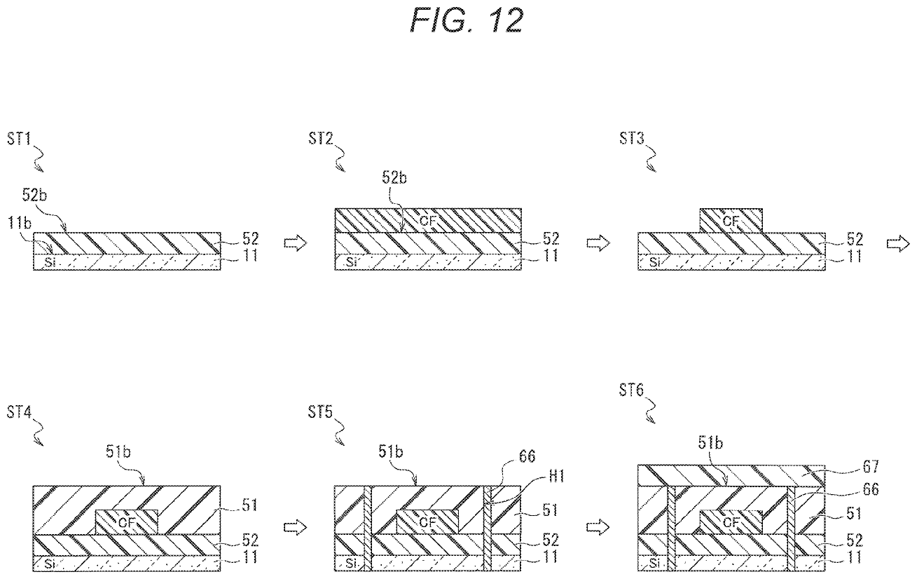

The imaging apparatus 1 according to the embodiment of the present disclosure may include, as the pixel region 3, any one of pixel regions 3A to 3H exemplified in following configuration examples 1 to 8, or may have a configuration obtained by optionally combining the pixel regions 3A to 3H. Furthermore, the pixel region 3 may be manufactured by any one of manufacturing methods in FIGS. 12 to 15 to be described later.

### Configuration Example 1

FIG. 3 is a cross-sectional view illustrating the pixel region 3A (configuration example 1) according to the embodiment of the present disclosure. As illustrated in FIG. 3, the pixel region 3A includes the color filter CF provided on the back surface 11b (an example of “one surface” of the present disclosure) side of the semiconductor substrate 11, the first sealing material 51 provided on the back surface 11b side of the semiconductor substrate 11 to cover the color filter CF, and the second sealing material 52 provided between the semiconductor substrate 11 and the color filter CF.

The color filter CF illustrated in FIG. 3 may be, for example, a blue color filter CF(B), a green color filter CF(B), or a red color filter CF(R). Furthermore, the color filter CF illustrated in FIG. 3 may include color filters of a plurality of colors in place of a single color. For example, as illustrated in FIG. 2, the color filter CF illustrated in FIG. 3 may include a red R color filter, a green G color filter, and a blue B color filter, and may have a configuration in which the color filters of the respective colors are arranged to form a predetermined pattern (as an example, Bayer array).

Note that, the blue color filter has a function of transmitting light of a blue wavelength band out of the visible light (for example, light having a wavelength of 400 nm or longer and 600 nm or shorter) and blocking light of other wavelength bands. The green color filter has a function of transmitting light of a green wavelength band out of the visible light and blocking light of other wavelength bands. The red color filter has a function of transmitting light of a red wavelength band out of the visible light and blocking light of other wavelength bands.

The first sealing material 51 includes a material capable of transmitting light of a wavelength band set in advance and having a thermal conductivity of 0.5 W/m·K or less. As the light of the wavelength band set in advance, the visible light (for example, light of a wavelength of 400 nm or longer and 600 nm or shorter) is exemplified. Furthermore, the light of the wavelength band set in advance may include the infrared light (for example, light of a wavelength of 800 nm or longer and 1200 nm or shorter). That is, it is possible that the first sealing material 51 may transmit light including wavelength bands from the visible light to infrared light.

The first sealing material 51 is, for example, an acrylic resin, a polyimide resin, a silicone resin, or a Bi/Si mixed inorganic material obtained by mixing bismuth and silicon. The thermal conductivity of each of these materials is 0.5 W/m·K or less as illustrated in Table 1 below. Therefore, the first sealing material 51 may have a heat shielding property. The first sealing material 51 may suppress heat transfer from the opposite side (an upper side in FIG. 3, and an on-chip microlens OCL side illustrated in FIG. 2 as an example) of the semiconductor substrate 11 across the first sealing material 51 to the color filter CF via the first sealing material 51.

TABLE 1

| Material type | Thermal conductivity (W/m · K) |
|---|---|
| Acrylic resin | 0.21 |
| Polyimide resin | 0.00024 |
| Silicone resin | 0.2 |
| Bi/Si (mixed inorganic) | 0.16 |
| Si (inorganic) | 168 |
| ZiO₂ (inorganic) | 3 |

A film thickness of the first sealing material 51 is preferably 0.1 μm or more and 3.0 μm or less, and more preferably 0.1 μm or more and 2.0 μm or less, for example. This makes it easy for the first sealing material 51 to achieve both excellent heat shielding property and excellent translucency. Furthermore, reducing the film thickness of the first sealing material 51 also contributes to height reduction of the imaging apparatus 1. Note that, a front surface 51b (an upper surface in FIG. 3) of the first sealing material 51 may be planarized by, for example, chemical mechanical polishing (CMP) treatment.

The second sealing material 52 includes a material capable of transmitting light of a wavelength band set in advance and having a thermal conductivity of 0.5 W/m·K or less. As the light of the wavelength band set in advance, the visible light is exemplified. Furthermore, the light of the wavelength band set in advance may include the infrared light. That is, it is possible that the second sealing material 52 may transmit light including wavelength bands from the visible light to infrared light.

The second sealing material 52 is, for example, an acrylic resin, a polyimide resin, a silicone resin, or a Bi/Si mixed inorganic material obtained by mixing bismuth and silicon. The thermal conductivity of each of these materials is 0.5 W/m·K or less as illustrated in Table 1. Therefore, the second sealing material 52 may have a heat shielding property. The second sealing material 52 may suppress heat transfer from the semiconductor substrate 11 side to the color filter CF via the second sealing material 52.

Furthermore, a film thickness of the second sealing material 52 is 0.1 μm or more and 3.0 μm or less, and preferably 0.1 μm or more and 2.0 μm or less, for example. This makes it easy for the second sealing material 52 to achieve both excellent heat shielding property and excellent translucency. Furthermore, reducing the film thickness of the second sealing material 52 also contributes to height reduction of the imaging apparatus 1. Note that, a front surface 52b (an upper surface in FIG. 3) of the second sealing material 52 may be planarized by, for example, CMP treatment.

### Configuration Example 2

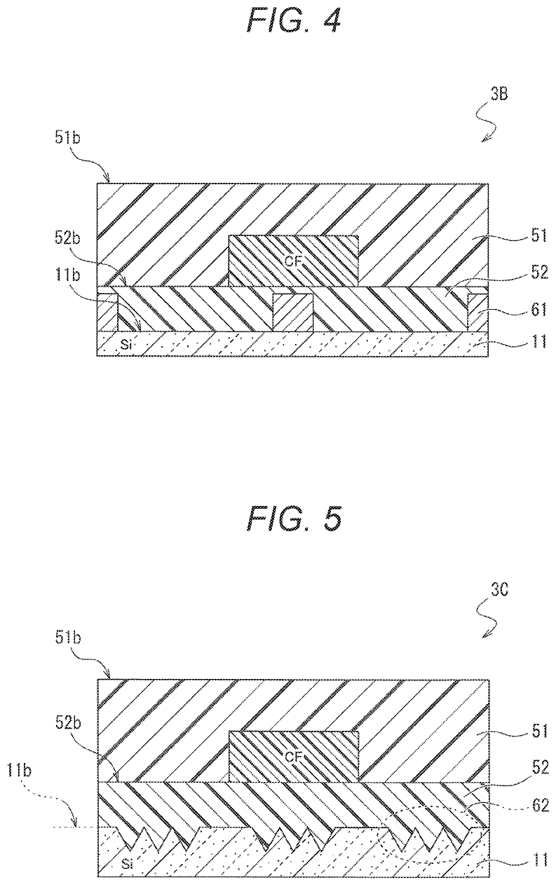

FIG. 4 is a cross-sectional view illustrating the pixel region 3B (configuration example 2) according to the embodiment of the present disclosure. As illustrated in FIG. 4, the pixel region 3B includes wiring 61 (an example of an “uneven structure” of the present disclosure) provided on the back surface 11b (an upper surface in FIG. 4) side of the semiconductor substrate 11. The wiring 61 includes metal such as tungsten, for example. The wiring 61 has a thickness of, for example, 0.1 μm or more and 3.0 μm or less. By arranging the wiring 61 having such thickness, unevenness is generated on the back surface 11b side of the semiconductor substrate 11.

The second sealing material 52 covers the wiring 61. The front surface 52b (an upper surface in FIG. 4) of the second sealing material 52 is planarized by, for example, CMP treatment. The color filter CF is provided on the planarized front surface 52b (the upper surface in FIG. 4) of the second sealing material 52. In this example also, the color filter CF is covered with the first sealing material 51.

### Configuration Example 3

FIG. 5 is a cross-sectional view illustrating the pixel region 3C (configuration example 3) according to the embodiment of the present disclosure. As illustrated in FIG. 5, in the pixel region 3C, a rig structure 62 (an example of an “uneven structure” of the present disclosure) is formed on the back surface 11b (an upper surface in FIG. 4) of the semiconductor substrate 11. The rig structure 62 may be referred to as an uneven portion. There is a case where the rig structure 62 promotes incidence of light on the back surface 11b of the semiconductor substrate 11. For example, the rig structure 62 promotes incidence of long-wavelength light on the back surface 11b while preventing scattering of the long-wavelength light.

Furthermore, since a surface area of the back surface 11b is increased by the rig structure 62, thermal conduction of the back surface 11b becomes easy. However, the second sealing material 52 is arranged between the back surface 11b and the color filter CF. Therefore, the thermal conduction from the back surface 11b to the color filter CF is suppressed.

The rig structure 62 is formed by performing dry etching on the back surface 11b (the upper surface in FIG. 5) of the semiconductor substrate 11, for example. The rig structure 62 may be embedded with the second sealing material 52 or may be embedded with another film. In this example also, the color filter CF is covered with the first sealing material 51.

### Configuration Example 4

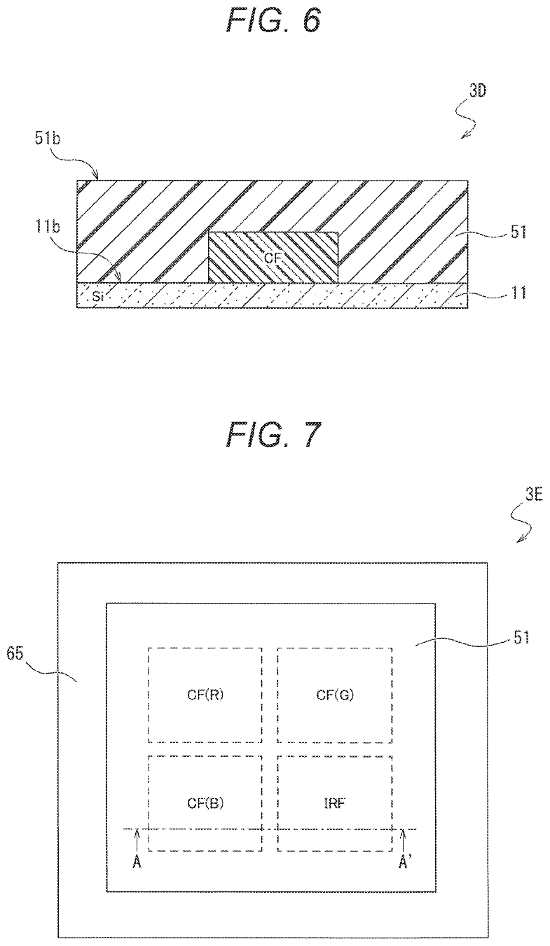

FIG. 6 is a cross-sectional view illustrating the pixel region 3D (configuration example 4) according to the embodiment of the present disclosure. As illustrated in FIG. 6, in the pixel region 3D, the second sealing material 52 is not provided. The color filter CF is directly provided on the back surface 11b (an upper surface in FIG. 6) of the semiconductor substrate 11 without the second sealing material 52. In this example also, the color filter CF is covered with the first sealing material 51.

### Configuration Example 5

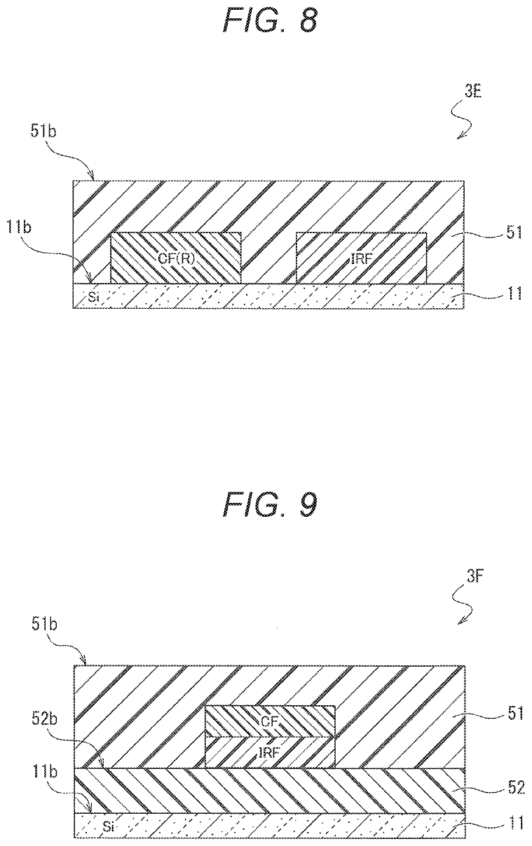

FIG. 7 is a plan view illustrating the pixel region 3E (configuration example 5) according to the embodiment of the present disclosure. FIG. 8 is a cross-sectional view illustrating the pixel region 3E (configuration example 5) according to the embodiment of the present disclosure. FIG. 8 illustrates a cross section taken along line A-A′ of the plan view illustrated in FIG. 7. As illustrated in FIGS. 7 and 8, the pixel region 3E includes a red color filter CF(R), a green color filter CF(G), a blue color filter CF(B), and an IR filter IRF arranged side by side in a horizontal direction. The horizontal direction is a direction orthogonal to a thickness direction of the color filter CF, and is, for example, a direction orthogonal to the back surface 11b (an upper surface in FIG. 8) of the semiconductor substrate 11.

The IR filter IRF has a function of transmitting the infrared light and blocking the visible light. The IR filter having a function of transmitting the infrared light and blocking the visible light may be referred to as an IR pass filter. Alternatively, the IR filter IRF may have a function of transmitting the visible light and blocking the infrared light. The IR filter having a function of transmitting the visible light and blocking the infrared light may be referred to as an IR cut filter.

In the pixel region 3E, for example, the IR pass filter is used as the IR filter IRF. Therefore, the photodiode PD (refer to FIG. 2) in the pixel region 3E may photoelectrically convert the infrared light by the photodiode PD to output. It is possible to suppress noise due to the visible light from being included in a detection signal of the infrared light.

As illustrated in FIG. 7, in the pixel region 3E, one red color filter CF(R), one green color filter CF(G), one blue color filter CF(B), and one IR filter IRF form one pixel group, for example. A plurality of pixel groups is arranged side by side in a longitudinal direction and a lateral direction in plan view.

As illustrated in FIG. 7, each pixel group may be surrounded by a partition wall 65. The partition wall 65 includes a material having a light shielding property so as to block the visible light and infrared light. Examples of the material having the light shielding property include metal, a black resin or the like. The partition wall 65 may block light from one of the pixel groups adjacent to each other toward the other, and may suppress optical color mixing between the adjacent pixel groups.

In this example, the red color filter CF(R), the green color filter CF(G), the blue color filter CF(B), and the IR filter IRF are covered with the first sealing material 51. The partition wall 65 may be covered with the first sealing material 51 or may be exposed from the first sealing material 51.

Note that, FIG. 8 illustrates a case where the color filter CF(B) and the IR pass filter are directly provided on the back surface 11b (an upper surface in FIG. 8) of the semiconductor substrate 11, but the configuration of the pixel region 3E is not limited thereto. The second sealing material 52 (refer to FIG. 3, for example) may be provided between the color filter CF and the semiconductor substrate 11 also in the pixel region 3E. The second sealing material 52 may also be provided between the IR filter IRF and the semiconductor substrate 11. The second sealing material 52 may be provided in an entire pixel region 3E.

### Configuration Example 6

FIG. 9 is a cross-sectional view illustrating the pixel region 3F (configuration example 6) according to the embodiment of the present disclosure. As illustrated in FIG. 9, in the pixel region 3F, the color filter CF is stacked on the IR filter IRF. For example, the IR filter IRF is provided on the front surface 52b (an upper surface in FIG. 9) of the second sealing material 52, and the color filter CF is provided on the IR filter IRF. The color filter CF is any one of the red color filter CF(R), the green color filter CF(G), and the blue color filter CF(B). In this example also, the color filter CF is covered with the first sealing material 51.

In the pixel region 3F, for example, the IR cut filter is used as the IR filter IRF. Therefore, the photodiode PD in the pixel region 3F may photoelectrically convert light transmitted through the color filter CF from which the infrared light is removed to output. It is possible to suppress noise due to the infrared light from being included in a detection signal of the visible light.

Note that, in this example also, it is possible that the second sealing material 52 is not provided. The IR filter IRF may be directly provided on the back surface 11b (an upper surface in FIG. 9) of the semiconductor substrate 11 without the second sealing material 52.

Furthermore, in this example, a positional relationship in stacking of the color filter CF and the IR filter IRF may be inverted. For example, the color filter CF may be provided on the front surface 52b (the upper surface in FIG. 9) of the second sealing material 52, and the IR filter IRF may be provided on the color filter CF. In this case, the IR filter IRF is covered with the first sealing material 51. The color filter CF is indirectly covered with the first sealing material 51 via the IR filter IRF.

### Configuration Example 7

FIG. 10 is a cross-sectional view illustrating the pixel region 3G (configuration example 7) according to the embodiment of the present disclosure. As illustrated in FIG. 10, in the pixel region 3G, the color filter CF is stacked on the IR filter IRF via the second sealing material 52. Furthermore, a third sealing material 53 is provided between the IR filter IRF and the semiconductor substrate 11.

For example, the third sealing material 53 is provided on the back surface 11b (an upper surface in FIG. 10) side of the semiconductor substrate 11, and the IR filter IRF is provided on a front surface 53b (an upper surface in FIG. 10) of the third sealing material 53. Furthermore, the second sealing material 52 is provided on the front surface 53b of the third sealing material 53 and covers the IR filter IRF. The color filter CF is provided on the planarized front surface 52b (an upper surface in FIG. 10) of the second sealing material 52. The first sealing material 51 is provided on the planarized front surface 52b of the second sealing material 52 to cover the color filter CF.

As is the case with the pixel region 3F illustrated in FIG. 9, the color filter CF is any one of the red color filter CF(R), the green color filter CF(G), and the blue color filter CF(B). In this example also, the color filter CF is covered with the first sealing material 51.

The third sealing material 53 includes a material capable of transmitting light of a wavelength band set in advance and having a thermal conductivity of 0.5 W/m·K or less. As the light of the wavelength band set in advance, both the visible light and infrared light are exemplified.

The third sealing material 53 is, for example, an acrylic resin, a polyimide resin, a silicone resin, or a Bi/Si mixed inorganic material obtained by mixing bismuth and silicon. The thermal conductivity of each of these materials is 0.5 W/m·K or less as illustrated in Table 1. Therefore, the third sealing material 53 may have a heat shielding property. The third sealing material 53 may suppress heat transfer from the semiconductor substrate 11 side to the IR filter IRF via the third sealing material 53.

Note that, in this example also, a positional relationship in stacking of the color filter CF and the IR filter IRF may be inverted. In this case, the IR filter IRF is covered with the first sealing material 51. The color filter CF is indirectly covered with the first sealing material 51 via the IR filter IRF and the second sealing material 52.

### Configuration Example 8

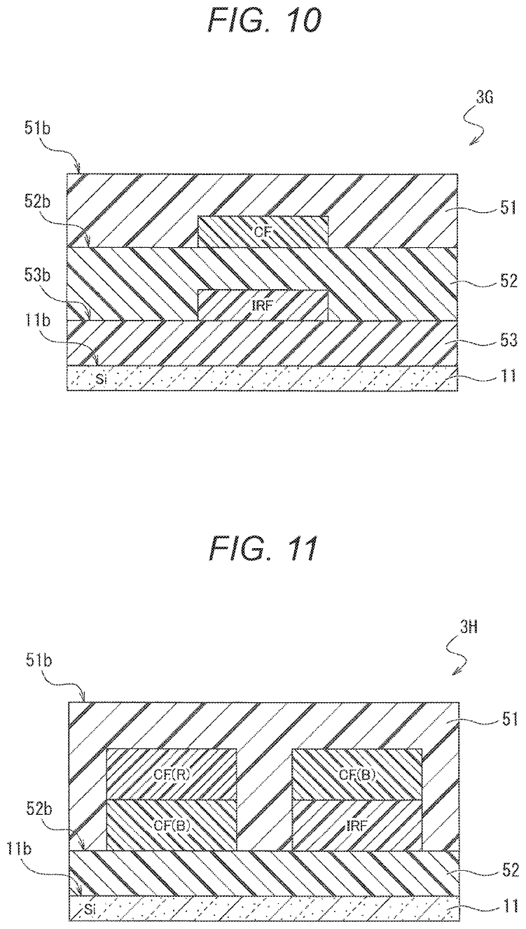

FIG. 11 is a cross-sectional view illustrating the pixel region 3H (configuration example 8) according to the embodiment of the present disclosure. As illustrated in FIG. 11, in the pixel region 3H, a first color filter CF is stacked on the IR filter IRF. Furthermore, a third color filter CF is stacked on a second color filter CF. Each of the first to third color filters CF is any one of the red color filter CF(R), the green color filter CF(G), and the blue color filter CF(B).

The first color filter CF and the second color filter CF may be color filters of the same color or may be color filters of different colors. Similarly, the first color filter CF and the third color filter CF may be color filters of the same color or may be color filters of different colors. The second color filter CF and the third color filter CF may be color filters of the same color or may be color filters of different colors.

In this example also, the color filter CF is directly or indirectly covered with the first sealing material 51.

<Manufacturing Method of Imaging Apparatus>

Next, a plurality of examples of a manufacturing method of the imaging apparatus according to the embodiment of the present disclosure is described. Note that, the imaging apparatus is manufactured using various types of devices such as a film forming device (including a chemical vapor deposition (CVD) device, a thermal oxidation furnace, a sputtering device, a spin coater, a resist applying device and the like), an exposure device, an ion implantation device, an annealing device, an etching device, and a chemical mechanical polishing (CMP) device. Hereinafter, these devices are collectively referred to as manufacturing devices.

### Manufacturing Method_Example 1

FIG. 12 is a cross-sectional view illustrating a manufacturing method_example 1 of the imaging apparatus 1 according to the embodiment of the present disclosure. As illustrated at step ST1 in FIG. 12, the manufacturing device forms the second sealing material 52 on the back surface 11b (an upper surface in FIG. 12) of the semiconductor substrate 11. The second sealing material 52 is formed by spin coating, for example.

Next, as illustrated at step ST2 in FIG. 12, the manufacturing device forms the color filter CF on the front surface 52b (an upper surface in FIG. 12) of the second sealing material 52. The color filter CF is formed by spin coating, for example. Next, as illustrated at step ST3 in FIG. 12, the manufacturing device patterns the color filter CF into a shape set in advance using a lithography technology. The manufacturing device performs steps ST2 and ST3 in FIG. 12 for each color of the color filter CF. Furthermore, although not illustrated, the manufacturing device may form the IR filter IRF in addition to the color filter CF.

Next, as illustrated at step ST4 in FIG. 12, the manufacturing device forms the first sealing material 51 on the front surface 52b (the upper surface in FIG. 12) of the second sealing material 52. The first sealing material 51 is formed by spin coating, for example.

Next, the manufacturing device forms, for example, a resist pattern (not illustrated) on the front surface 51b (an upper surface in FIG. 12) of the first sealing material 51, and performs dry etching processing on the first sealing material 51 and the second sealing material 52 using the resist pattern as a mask. Therefore, as illustrated at step ST5 in FIG. 12, the manufacturing device forms a through hole H1 in the first sealing material 51 and the second sealing material 52. Note that, the through hole H1 may reach the inside of the semiconductor substrate 11. Next, the manufacturing device embeds metal in the through hole H1 to form an electrode 66.

Next, as illustrated at step ST6 in FIG. 12, the manufacturing device forms a functional film 67 having a desired function on the front surface 51b of the first sealing material 51. The functional film 67 may be a protective film having a function of protecting the pixel region, the on-chip microlens OCL (refer to FIG. 2) having a light condensing function, or a film having other functions. In the embodiment of the present disclosure, the functional film 67 has an optional function.

Furthermore, the functional film 67 may include an organic material or an inorganic material. In the embodiment of the present disclosure, the material forming the functional film 67 is optional.

Next, the manufacturing device performs heat treatment at high temperature (for example, 250° C. or higher) to an entire substrate on which the functional film 67 is formed to cure the functional film 67. Through the above-described steps, the pixel region 3 (for example, the pixel region 3A illustrated in FIG. 3) of the imaging apparatus 1 is completed.

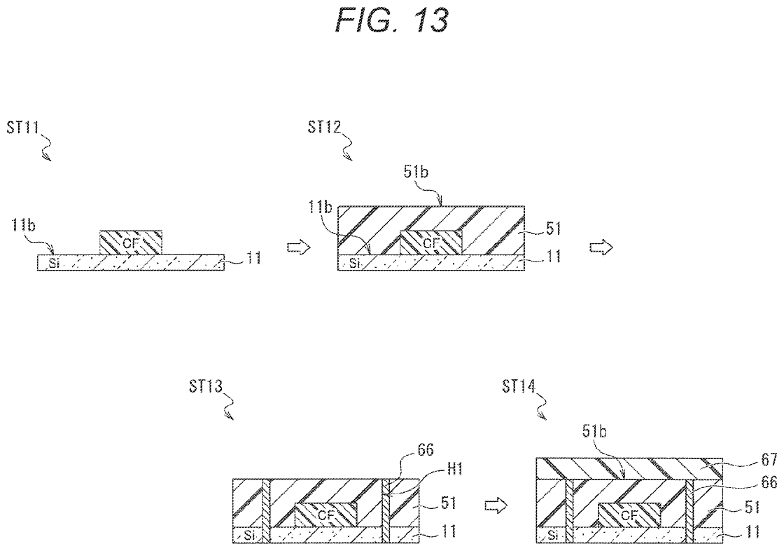

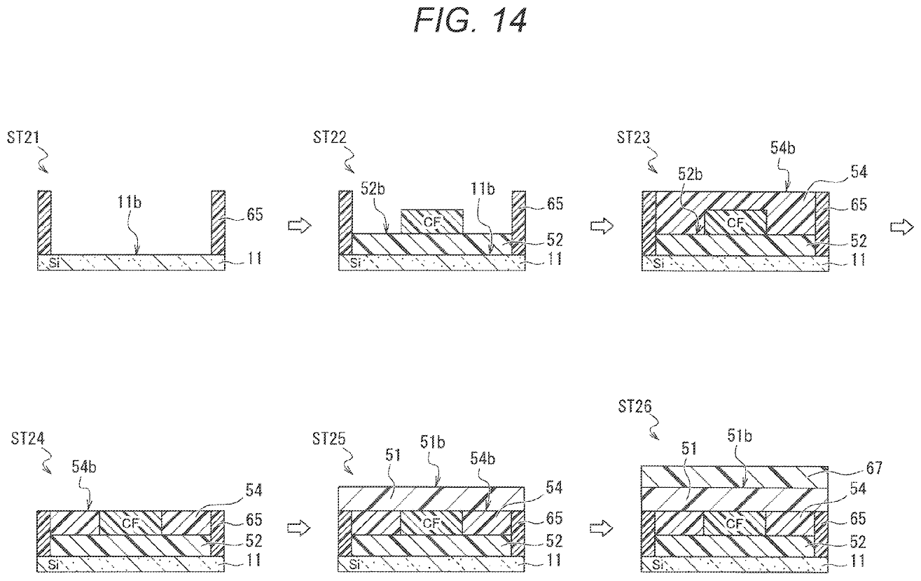

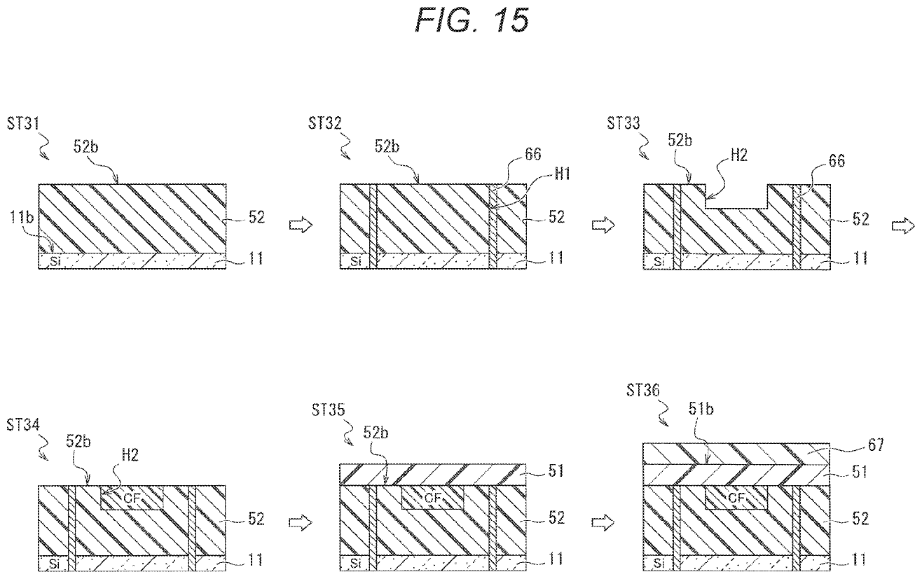

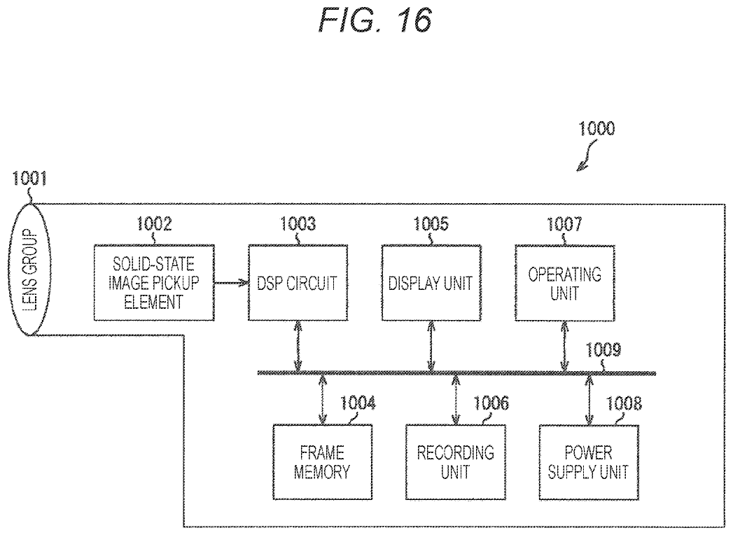

Note that, in the manufacturing method according to the embodiment of the present disclosure, a step of forming the functional film 67 may be omitted. For example, at step ST6 illustrated in FIG. 12, step ST14 in FIG. 13 to be described later, step ST26 in FIG. 14 to be described later, and step ST36 in FIG. 15 to be described later, the step of forming the functional film 67 may be omitted. After the first sealing material 51 is formed, heat treatment at high temperature may be performed without the step of forming the functional film 67.

### Manufacturing Method_Example 2

FIG. 13 is a cross-sectional view illustrating a manufacturing method_example 2 of the imaging apparatus 1 according to the embodiment of the present disclosure. As illustrated at step ST11 in FIG. 13, the manufacturing device forms the color filter CF on the back surface 11b (an upper surface in FIG. 13) of the semiconductor substrate 11. Next, the manufacturing device patterns the color filter CF into a shape set in advance using a lithography technology. The manufacturing device forms the color filter CF and patterns the same for each color of the color filter CF. Furthermore, although not illustrated, the manufacturing device may form the IR filter IRF in addition to the color filter CF.

Next, as illustrated at step ST12 in FIG. 13, the manufacturing device forms the first sealing material 51 on the back surface 11b of the semiconductor substrate 11. The first sealing material 51 is formed by spin coating, for example.

Next, the manufacturing device forms, for example, a resist pattern (not illustrated) on the front surface 51b of the first sealing material 51, and performs dry etching processing on the first sealing material 51 using the resist pattern as a mask. Therefore, as illustrated at step ST13 in FIG. 13, the manufacturing device forms a through hole H1 in the first sealing material 51. Note that, the through hole H1 may reach the inside of the semiconductor substrate 11. Next, the manufacturing device embeds metal in the through hole H1 to form an electrode 66.

Next, as illustrated at step ST14 in FIG. 13, the manufacturing device forms a functional film 67 having a desired function on the front surface 51b of the first sealing material 51. Next, the manufacturing device performs heat treatment to the entire substrate on which the functional film 67 is formed to cure the functional film 67. Through the above-described steps, the pixel region 3 (for example, the pixel region 3D illustrated in FIG. 6) of the imaging apparatus 1 is completed.

### Manufacturing Method_Example 3

FIG. 14 is a cross-sectional view illustrating a manufacturing method_example 3 of the imaging apparatus 1 according to the embodiment of the present disclosure. As illustrated at step ST21 in FIG. 14, the manufacturing device forms the partition wall 65 on the back surface 11b (an upper surface in FIG. 14) of the semiconductor substrate 11. For example, the manufacturing device forms the partition wall 65 by forming a material film (not illustrated) including metal, a black resin or the like on the back surface 11b of the semiconductor substrate 11, forming a resist pattern (not illustrated) on the material film, and performing dry etching on the material film using the resist pattern as a mask.

Next, as illustrated at step ST22 in FIG. 14, the manufacturing device forms the second sealing material 52 in a region surrounded by the partition wall 65 on the back surface 11b of the semiconductor substrate 11. The second sealing material 52 is formed by spin coating, for example.

Next, as illustrated at step ST22 in FIG. 14, the manufacturing device forms the color filter CF on the front surface 52b (an upper surface in FIG. 14) of the second sealing material 52, and patterns the color filter CF into a shape set in advance using a lithography technology. The manufacturing device forms the color filter CF and patterns the same for each color of the color filter CF. Furthermore, although not illustrated, the manufacturing device may form the IR filter IRF in addition to the color filter CF.

Next, as illustrated at step ST23 in FIG. 14, the manufacturing device forms a fourth sealing material 54 on the front surface 52b (the upper surface in FIG. 14) of the second sealing material 52. The fourth sealing material 54 is formed by spin coating, for example.

The fourth sealing material 54 may include a material capable of transmitting light of a wavelength band set in advance and having a thermal conductivity of 0.5 W/m·K or less. As the light of the wavelength band set in advance, the visible light is exemplified. Furthermore, the light of the wavelength band set in advance may include the infrared light. That is, it is possible that the fourth sealing material 54 may transmit light including wavelength bands from the visible light to infrared light.

The fourth sealing material 54 is, for example, an acrylic resin, a polyimide resin, a silicone resin, or a Bi/Si mixed inorganic material obtained by mixing bismuth and silicon. The thermal conductivity of each of these materials is 0.5 W/m·K or less as illustrated in Table 1. Therefore, the fourth sealing material 54 may have a heat shielding property. The fourth sealing material 54 may suppress heat transfer to the color filter CF via the fourth sealing material 54.

Next, as illustrated at step ST24 in FIG. 14, the manufacturing device performs CMP treatment on the front surface 54b (an upper surface in FIG. 14) of the fourth sealing material 54 to planarize. By this planarization, an upper surface of the color filter CF is exposed from the fourth sealing material 54.

Next, as illustrated at step ST25 in FIG. 14, the manufacturing device forms the first sealing material 51 on the planarized front surface 54b of the fourth sealing material 54 to cover the color filter CF. The first sealing material 51 is formed by spin coating, for example.

Next, as illustrated at step ST26 in FIG. 14, the manufacturing device forms a functional film 67 having a desired function on the front surface 51b of the first sealing material 51. Next, the manufacturing device performs heat treatment to the entire substrate on which the functional film 67 is formed to cure the functional film 67. Through the above-described steps, the pixel region 3 (for example, the pixel region 3E including the partition wall 65 illustrated in FIG. 7) of the imaging apparatus 1 is completed.

### Manufacturing Method_Example 4

FIG. 15 is a cross-sectional view illustrating a manufacturing method_example 4 of the imaging apparatus 1 according to the embodiment of the present disclosure. As illustrated at step ST31 in FIG. 15, the manufacturing device forms the second sealing material 52 on the back surface 11b (an upper surface in FIG. 15) of the semiconductor substrate 11. The second sealing material 52 is formed by spin coating, for example.

Next, as illustrated at step ST32 in FIG. 15, the manufacturing device forms a through hole H1 in the second sealing material 52 by using a lithography technology and a dry etching technology. Note that, the through hole H1 may reach the inside of the semiconductor substrate 11. Next, the manufacturing device embeds metal in the through hole H1 to form an electrode 66.

Next, as illustrated at step ST33 in FIG. 15, the manufacturing device forms a recess H2 on the front surface 52b (an example of an “opposite side of a surface facing the semiconductor substrate” of the present disclosure, an upper surface in FIG. 15) of the second sealing material 52 by using a lithography technology and a dry etching technology.

Next, the manufacturing device forms the color filter CF on the front surface 52b of the second sealing material 52, and patterns the color filter CF into a shape set in advance using a lithography technology. Therefore, as illustrated at step ST34 in FIG. 15, the manufacturing device forms the color filter CF arranged in the recess H2. The manufacturing device forms the color filter CF and patterns the same. Furthermore, although not illustrated, the manufacturing device may form the IR filter IRF in addition to the color filter CF.

Next, as illustrated at step ST35 in FIG. 15, the manufacturing device forms the first sealing material 51 on the front surface 52b (the upper surface in FIG. 15) of the second sealing material 52 to cover the color filter CF. The first sealing material 51 is formed by spin coating, for example.

Next, as illustrated at step ST36 in FIG. 15, the manufacturing device forms the functional film 67 having a desired function on the front surface 51b (an upper surface in FIG. 15) of the first sealing material 51. Next, the manufacturing device performs heat treatment to the entire substrate on which the functional film 67 is formed to cure the functional film 67. Through the above-described steps, the pixel region 3 of the imaging apparatus 1 is completed.

### Effect of Embodiment

As described above, the imaging apparatus 1 according to the embodiment of the present disclosure includes the semiconductor substrate 11, the color filter CF provided on the back surface 11b side of the semiconductor substrate 11, and the first sealing material 51 provided on the back surface 11b side of the semiconductor substrate 11 to cover the color filter CF. The first sealing material 51 includes a material capable of transmitting light of a wavelength band set in advance (for example, the visible light, or the visible light and infrared light) and having a thermal conductivity of 0.5 W/m·K or less.

With this arrangement, since the color filter CF is covered with the first sealing material 51, the first sealing material 51 suppresses thermal conduction to the color filter CF even in a case where heat treatment at high temperature (for example, 250° C. or higher) is performed after the first sealing material 51 is formed. Since the first sealing material 51 protects the color filter CF from the heat treatment at high temperature, heat resistance of the color filter CF may be enhanced.

Furthermore, a film thickness of the first sealing material 51 may be 0.1 μm or more and 3.0 μm or less. The heat shielding property is expected to be improved as the film thickness of the first sealing material 51 is thicker, but in contrast, there is a possibility that a disadvantage occurs such that incident light is greatly attenuated in the process of transmission through the first sealing material 51, or height reduction of the imaging apparatus 1 is hindered. When the film thickness of the first sealing material 51 is within the above-described range, it is possible to enhance the heat resistance of the color filter CF while suppressing the above-described disadvantage.

Furthermore, the imaging apparatus 1 according to the embodiment of the present disclosure may further include the second sealing material 52 provided between the semiconductor substrate 11 and the color filter CF. The second sealing material 52 includes a material capable of transmitting light of a wavelength band set in advance (for example, the visible light, or the visible light and infrared light) and having a thermal conductivity of 0.5 W/m·K or less. With this arrangement, the second sealing material 52 suppresses thermal conduction from the semiconductor substrate 11 side to the color filter CF. Since the second sealing material 52 in addition to the first sealing material 51 protects the color filter CF from the heat treatment at high temperature, the heat resistance of the color filter CF may be further enhanced.

The manufacturing method of the imaging apparatus 1 according to the embodiment of the present disclosure includes a step of forming the color filter CF on the back surface 11b side of the semiconductor substrate 11, a step of forming the first sealing material 51 on the back surface 11b side of the semiconductor substrate 11 to cover the color filter CF, and a step of performing heat treatment on the entire substrate including the semiconductor substrate 11, the color filter CF, and the first sealing material 51 after forming the first sealing material 51. A material capable of transmitting light of a wavelength band set in advance (for example, the visible light, or the visible light and infrared light) and having a thermal conductivity of 0.5 W/m·K or less is used as the first sealing material 51.

With this arrangement, the first sealing material 51 suppresses the thermal conduction to the color filter CF even in a case where the heat treatment at high temperature (for example, 250° C. or higher) is performed after the first sealing material 51 is formed. Since the first sealing material 51 protects the color filter CF from the heat treatment at high temperature, heat resistance of the color filter CF may be enhanced.

### Example

Examples and comparative examples of the present disclosure are illustrated in Table 2. Note that, the technical scope of the present disclosure is not limited to the following Examples.

TABLE 2

| | | Base | | Sealing | | | Film | | |
|---|---|---|---|---|---|---|---|---|---|
| | | film | | film | Thermal | | thick- | | |
| | Sealing | thick- | Color | thick- | conduc- | Spectral | ness | CMP | DRY |
| | material | ness | filter | ness | tivity | fluctua- | reduc- | process- | process- |
| | type | (μm) | type | (μm) | (W/m · K) | tion | tion | ing | ing |
| Example 1 | Acrylic | 1 | BLUE | 1 | 0.25 | A | B | A | A |
| | resin | | | | | | | | |
| Example 2 | Polyimide | 1 | BLUE | 1 | 0.01 | B | A | C | A |
| | resin | | | | | | | | |
| Example 3 | Silicone | 1 | BLUE | 1 | 0.2 | A | A | B | A |
| | resin | | | | | | | | |
| Example 4 | Bi/Si | 1 | BLUE | 1 | 0.18 | B | A | A | A |
| | mixed | | | | | | | | |
| | material | | | | | | | | |
| Example 5 | Acrylic | 1 | RED | 1 | 0.25 | A | B | A | A |
| | resin | | | | | | | | |
| Example 6 | Acrylic | 1 | GREEN | 1 | 0.25 | A | B | A | A |
| | resin | | | | | | | | |
| Example 7 | Acrylic | 1 | IRF | 1 | 0.25 | A | B | A | A |
| | resin | | | | | | | | |
| Example 8 | Acrylic | 0 | BLUE | 1 | 0.35 | B | C | A | A |
| | resin | | | | | | | | |
| Example 9 | Acrylic | 0 | BLUE | 3 | 0.3 | A | B | A | A |
| | resin | | | | | | | | |
| Example 10 | Acrylic | 2 | BLUE | 0.1 | 0.35 | B | C | A | A |
| | resin | | | | | | | | |
| Example 11 | Acrylic | 2 | BLUE | 2 | 0.22 | A | B | A | A |
| | resin | | | | | | | | |
| Example 12 | Acrylic | 0.1 | BLUE | 0.1 | 0.48 | C | C | A | A |
| | resin | | | | | | | | |
| Comparative | ZiO₂ | 3 | BLUE | 3 | 3.5 | D | D | C | B |
| example 1 | | | | | | | | | |
| Comparative | Acrylic | 1 | BLUE | 0 | 0.55 | D | D | A | A |
| example 1 | | | | | | | | | |

In Table 2, a sealing material type means a type of the first sealing material. A base film thickness means a film thickness of the second sealing material. The base film thickness of 0 μm means a case where the second sealing material is not provided. A color filter type means a type of color of the color filter. In the color filter type, BLUE means a blue color filter, RED means a red color filter, and GREEN means a green color filter. Furthermore, IRF means a case where the IR filter is used in place of the color filter. A sealing film thickness means a film thickness of the first sealing material. Thermal conductivity means the thermal conductivity of the first sealing material. Spectral fluctuation, film thickness reduction, CMP processing, and DRY processing are evaluation results.

(Spectral Fluctuation)

In Table 2, spectral fluctuation means a fluctuation rate of a spectral curve before and after the heat treatment after the sealing film (first sealing material) is formed. Note that, in the Examples and Comparative Examples, a condition for the heat treatment is 300° C. and 300 minutes in an inert gas atmosphere. In initial comparison (that is, comparison with before heat treatment), a case where the fluctuation rate of the spectral curve was less than 1% was evaluated as A, a case where the fluctuation rate of the spectral curve was less than 2% was evaluated as B, a case where the fluctuation rate of the spectral curve was less than 3% was evaluated as C, and a case where the fluctuation rate of the spectral curve was 3% or more was evaluated as D. The fluctuation rate of the spectral curve is preferably as small as possible. In the evaluation of the spectral fluctuation, A, B, or C was regarded as acceptable, and D was regarded as unacceptable. As illustrated in Table 2, the evaluation results of the spectral fluctuation were A, B, or C in Examples 1 to 12, whereas D in Comparative Examples 1 and 2.

(Film Thickness Reduction)

In Table 2, film thickness reduction means a reduction rate of the film thickness before and after the heat treatment after the sealing film (first sealing material) is formed. In initial comparison, a case where the reduction rate of the film thickness was less than 1% was evaluated as A, a case where the reduction rate of the film thickness was less than 2% was evaluated as B, a case where the reduction rate of the film thickness was less than 3% was evaluated as C, and a case where the reduction rate of the film thickness was 3% or more was evaluated as D. The reduction rate of the film thickness is preferably as small as possible. In the evaluation of the film thickness reduction, A, B, or C was regarded as acceptable, and D was regarded as unacceptable. As illustrated in Table 2, the evaluation results of the film thickness reduction were A, B, or C in Examples 1 to 12, whereas D in Comparative Examples 1 and 2.

(CMP Processing)

In Table 2, CMP processing means variation (flatness) in in-plane film thickness of 12 inches after the CMP treatment. A case where the variation in in-plane film thickness was less than 1% was evaluated as A, a case where the variation in in-plane film thickness was less than 2% was evaluated as B, a case where the variation in in-plane film thickness was less than 3% was evaluated as C, and a case where the variation in in-plane film thickness was 3% or more was evaluated as D. The variation in in-plane film thickness is preferably as small as possible. In the evaluation of the CMP processing, A, B, or C was regarded as acceptable, and D was regarded as unacceptable. As illustrated in Table 2, the evaluation results of the CMP processing were A, B, or C in Examples 1 to 12 and Comparative Examples 1 and 2. Note that, in this evaluation, 300 points in a plane were measured on a 12-inch wafer, and flatness by CMP processing was evaluated using a calculation formula of (maximum film thickness−minimum film thickness)/average film thickness×100.

(DRY Processing)

In Table 2, DRY processing means perpendicularity (that is, anisotropy) of DRY etching. In this evaluation, a case where widths of upper and lower portions of a cavity portion formed into a groove by the DRY processing coincide with each other is expressed as perpendicular. A case where (width deviation) of the processed upper and lower portions was less than 1% was evaluated as A, a case where width deviation was less than 2% was evaluated as B, a case where width deviation was less than 3% was evaluated as C, and a case where width deviation was 3% or more was evaluated as D. The width variation is preferably as small as possible. In the evaluation of the DRY processing, A, B, or C was regarded as acceptable, and D was regarded as unacceptable. As illustrated in Table 2, the evaluation results of the DRY processing were A in Examples 1 to 12 and Comparative Example 2, and B in Comparative Example 1.

(Overall Evaluation)

In all of Examples 1 to 12, the respective evaluation results of the spectral fluctuation, film thickness reduction, CMP processing, and DRY processing were A, B, or C. In contrast, in Comparative Examples 1 and 2, the evaluation results of the spectral fluctuation and film thickness reduction were D. From the above, as overall evaluation, Examples 1 to 12 were determined to be acceptable, and Comparative Examples 1 and 2 were determined to be unacceptable.

<Electronic Device to which Imaging Apparatus is Applied>

Next, an electronic device to which the imaging apparatus 1 according to the embodiment of the present disclosure is applied is described. FIG. 16 is a block diagram illustrating a configuration example of an imaging apparatus 1000 according to the embodiment of the present disclosure. The imaging apparatus 1000 in FIG. 16 is an example of the electronic device to which the imaging apparatus 1 is applied, and is a video camera, a digital still camera and the like.

The imaging apparatus 1000 includes a lens group 1001, a solid-state image pickup element 1002, a DSP circuit 1003, a frame memory 1004, a display unit 1005, a recording unit 1006, an operating unit 1007, and a power supply unit 1008. The DSP circuit 1003, the frame memory 1004, the display unit 1005, the recording unit 1006, the operating unit 1007, and the power supply unit 1008 are connected to one another via a bus line 1009.

The lens group 1001 captures incident light (image light) from a subject and forms an image on an imaging surface of the solid-state image pickup element 1002.

The solid-state image pickup element 1002 is a CMOS image sensor, for example. The solid-state image pickup element 1002 converts an amount of the incident light the image of which is formed on the imaging surface by the lens group 1001 to an electrical signal for each pixel to supply to the DSP circuit 1003 as a pixel signal.

The configuration of the imaging apparatus 1 illustrated in FIGS. 1 and 2, the configuration of any one of the pixel regions 3 to 3H illustrated in FIGS. 3 to 11, or the imaging apparatus 1 manufactured by any one of the manufacturing methods in FIGS. 12 to 15 may be applied to the solid-state image pickup element 1002.

The DSP circuit 1003 performs predetermined image processing on the pixel signal supplied from the solid-state image pickup element 1002 and supplies the image signal after the image processing to the frame memory 1004 for each frame to temporarily store.

The display unit 1005 includes a panel display device such as a liquid crystal panel and an organic electro luminescence (EL) panel, for example, and displays an image on the basis of the pixel signal for each frame temporarily stored in the frame memory 1004.

The recording unit 1006 includes a digital versatile disk (DVD), a flash memory and the like, and reads the pixel signal for each frame temporarily stored in the frame memory 1004 to record.

The operating unit 1007 issues an operation command regarding various functions of the imaging apparatus 1000 under operation by a user. The power supply unit 1008 appropriately supplies power to the DSP circuit 1003, the frame memory 1004, the display unit 1005, the recording unit 1006, and the operating unit 1007.

It is sufficient that the electronic device to which the present technology is applied is a device in which the CMOS imaging sensor is used as an image capturing unit (photoelectric converting unit); there is a portable terminal device having an imaging function, a copying machine using the CMOS image sensor as an image reading unit and the like in addition to the imaging apparatus 1000.

### Other Embodiment

As described above, the present disclosure is described according to the embodiments and variations thereof, but it should not be understood that the description and drawings forming a part of this disclosure limit the present disclosure. Various alternative embodiments, examples, and operation techniques will be apparent to those skilled in the art from this disclosure. It is a matter of course that the present technology includes various embodiments and the like not described herein. At least one of various omissions, substitutions, and changes of the components may be made without departing from the gist of the above-described embodiments and variations. Furthermore, the effect described in this specification is illustrative only; the effect is not limited thereto and there may also be another effect.

### Application Example to Endoscopic Surgery System

The technology according to an embodiment of the present disclosure (present technology) is applicable to various products. For example, the technology according to an embodiment of the present disclosure may be applied to an endoscopic surgery system.

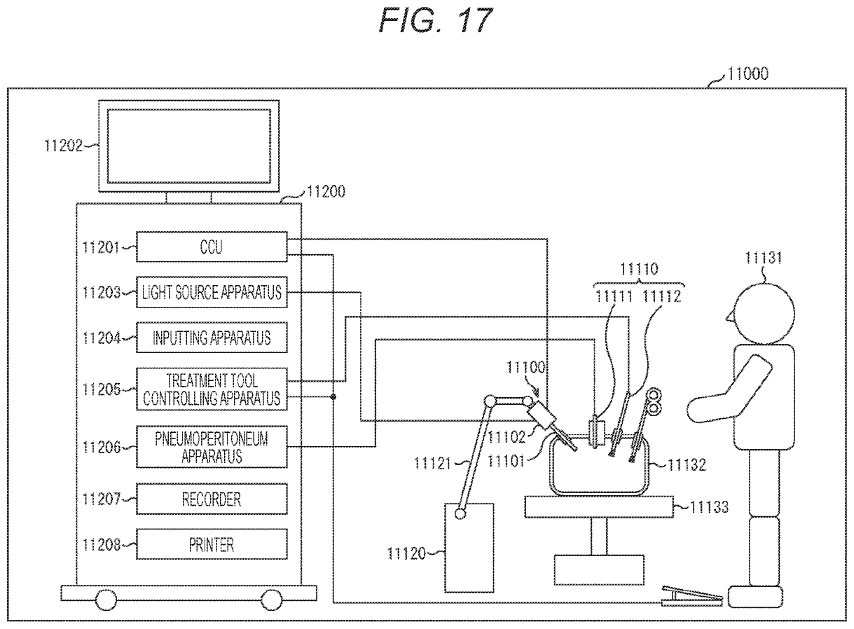

FIG. 17 is a view depicting an example of a schematic configuration of an endoscopic surgery system to which the technology according to an embodiment of the present disclosure (present technology) can be applied.

In FIG. 17, a state is illustrated in which a surgeon (medical doctor) 11131 is using an endoscopic surgery system 11000 to perform surgery for a patient 11132 on a patient bed 11133. As depicted, the endoscopic surgery system 11000 includes an endoscope 11100, other surgical tools 11110 such as a pneumoperitoneum tube 11111 and an energy device 11112, a supporting arm apparatus 11120 which supports the endoscope 11100 thereon, and a cart 11200 on which various apparatus for endoscopic surgery are mounted.

The endoscope 11100 includes a lens barrel 11101 having a region of a predetermined length from a distal end thereof to be inserted into a body cavity of the patient 11132, and a camera head 11102 connected to a proximal end of the lens barrel 11101. In the example depicted, the endoscope 11100 is depicted which includes as a rigid endoscope having the lens barrel 11101 of the hard type. However, the endoscope 11100 may otherwise be included as a flexible endoscope having the lens barrel 11101 of the flexible type.

The lens barrel 11101 has, at a distal end thereof, an opening in which an objective lens is fitted. A light source apparatus 11203 is connected to the endoscope 11100 such that light generated by the light source apparatus 11203 is introduced to a distal end of the lens barrel 11101 by a light guide extending in the inside of the lens barrel 11101 and is irradiated toward an observation target in a body cavity of the patient 11132 through the objective lens. It is to be noted that the endoscope 11100 may be a forward-viewing endoscope or may be an oblique-viewing endoscope or a side-viewing endoscope.

An optical system and an image pickup element are provided in the inside of the camera head 11102 such that reflected light (observation light) from the observation target is condensed on the image pickup element by the optical system. The observation light is photo-electrically converted by the image pickup element to generate an electric signal corresponding to the observation light, namely, an image signal corresponding to an observation image. The image signal is transmitted as RAW data to a camera control unit (CCU) 11201.

The CCU 11201 includes a central processing unit (CPU), a graphics processing unit (GPU) or the like and integrally controls operation of the endoscope 11100 and a display apparatus 11202. Further, the CCU 11201 receives an image signal from the camera head 11102 and performs, for the image signal, various image processes for displaying an image based on the image signal such as, for example, a development process (demosaic process).

The display apparatus 11202 displays thereon an image based on an image signal, for which the image processes have been performed by the CCU 11201, under the control of the CCU 11201.

The light source apparatus 11203 includes a light source such as, for example, a light emitting diode (LED) and supplies irradiation light upon imaging of a surgical region to the endoscope 11100.

An inputting apparatus 11204 is an input interface for the endoscopic surgery system 11000. A user can perform inputting of various kinds of information or instruction inputting to the endoscopic surgery system 11000 through the inputting apparatus 11204. For example, the user would input an instruction or a like to change an image pickup condition (type of irradiation light, magnification, focal distance or the like) by the endoscope 11100.

A treatment tool controlling apparatus 11205 controls driving of the energy device 11112 for cautery or incision of a tissue, sealing of a blood vessel or the like. A pneumoperitoneum apparatus 11206 feeds gas into a body cavity of the patient 11132 through the pneumoperitoneum tube 11111 to inflate the body cavity in order to secure the field of view of the endoscope 11100 and secure the working space for the surgeon. A recorder 11207 is an apparatus capable of recording various kinds of information relating to surgery. A printer 11208 is an apparatus capable of printing various kinds of information relating to surgery in various forms such as a text, an image or a graph.

It is to be noted that the light source apparatus 11203 which supplies irradiation light when a surgical region is to be imaged to the endoscope 11100 may include a white light source which includes, for example, an LED, a laser light source or a combination of them. Where a white light source includes a combination of red, green, and blue (RGB) laser light sources, since the output intensity and the output timing can be controlled with a high degree of accuracy for each color (each wavelength), adjustment of the white balance of a picked up image can be performed by the light source apparatus 11203. Further, in this case, if laser beams from the respective RGB laser light sources are irradiated time-divisionally on an observation target and driving of the image pickup elements of the camera head 11102 are controlled in synchronism with the irradiation timings. Then images individually corresponding to the R, G and B colors can be also picked up time-divisionally. According to this method, a color image can be obtained even if color filters are not provided for the image pickup element.

Further, the light source apparatus 11203 may be controlled such that the intensity of light to be outputted is changed for each predetermined time. By controlling driving of the image pickup element of the camera head 11102 in synchronism with the timing of the change of the intensity of light to acquire images time-divisionally and synthesizing the images, an image of a high dynamic range free from underexposed blocked up shadows and overexposed highlights can be created.

Further, the light source apparatus 11203 may be configured to supply light of a predetermined wavelength band ready for special light observation. In special light observation, for example, by utilizing the wavelength dependency of absorption of light in a body tissue to irradiate light of a narrow band in comparison with irradiation light upon ordinary observation (namely, white light), narrow band observation (narrow band imaging) of imaging a predetermined tissue such as a blood vessel of a superficial portion of the mucous membrane or the like in a high contrast is performed. Alternatively, in special light observation, fluorescent observation for obtaining an image from fluorescent light generated by irradiation of excitation light may be performed. In fluorescent observation, it is possible to perform observation of fluorescent light from a body tissue by irradiating excitation light on the body tissue (autofluorescence observation) or to obtain a fluorescent light image by locally injecting a reagent such as indocyanine green (ICG) into a body tissue and irradiating excitation light corresponding to a fluorescent light wavelength of the reagent upon the body tissue. The light source apparatus 11203 can be configured to supply such narrow-band light and/or excitation light suitable for special light observation as described above.

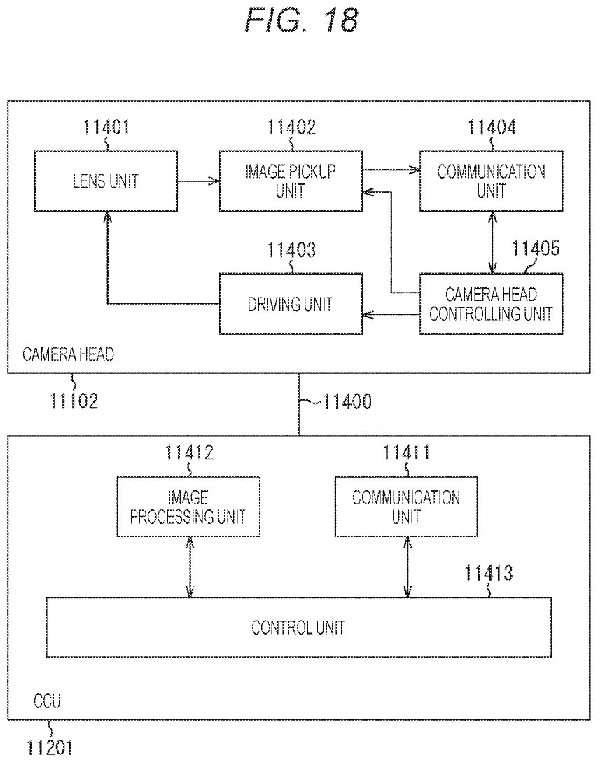

FIG. 18 is a block diagram depicting an example of a functional configuration of the camera head 11102 and the CCU 11201 depicted in FIG. 17.

The camera head 11102 includes a lens unit 11401, an image pickup unit 11402, a driving unit 11403, a communication unit 11404 and a camera head controlling unit 11405. The CCU 11201 includes a communication unit 11411, an image processing unit 11412 and a control unit 11413. The camera head 11102 and the CCU 11201 are connected for communication to each other by a transmission cable 11400.

The lens unit 11401 is an optical system, provided at a connecting location to the lens barrel 11101. Observation light taken in from a distal end of the lens barrel 11101 is guided to the camera head 11102 and introduced into the lens unit 11401. The lens unit 11401 includes a combination of a plurality of lenses including a zoom lens and a focusing lens.

The image pickup unit 11402 includes an image pickup element. The number of image pickup elements which is included by the image pickup unit 11402 may be one (single-plate type) or a plural number (multi-plate type). Where the image pickup unit 11402 is configured as that of the multi-plate type, for example, image signals corresponding to respective R, G and B are generated by the image pickup elements, and the image signals may be synthesized to obtain a color image. The image pickup unit 11402 may also be configured so as to have a pair of image pickup elements for acquiring respective image signals for the right eye and the left eye ready for three dimensional (3D) display. If 3D display is performed, then the depth of a living body tissue in a surgical region can be comprehended more accurately by the surgeon 11131. It is to be noted that, where the image pickup unit 11402 is configured as that of stereoscopic type, a plurality of systems of lens units 11401 are provided corresponding to the individual image pickup elements.

Further, the image pickup unit 11402 may not necessarily be provided on the camera head 11102. For example, the image pickup unit 11402 may be provided immediately behind the objective lens in the inside of the lens barrel 11101.

The driving unit 11403 includes an actuator and moves the zoom lens and the focusing lens of the lens unit 11401 by a predetermined distance along an optical axis under the control of the camera head controlling unit 11405. Consequently, the magnification and the focal point of a picked up image by the image pickup unit 11402 can be adjusted suitably.

The communication unit 11404 includes a communication apparatus for transmitting and receiving various kinds of information to and from the CCU 11201. The communication unit 11404 transmits an image signal acquired from the image pickup unit 11402 as RAW data to the CCU 11201 through the transmission cable 11400.

In addition, the communication unit 11404 receives a control signal for controlling driving of the camera head 11102 from the CCU 11201 and supplies the control signal to the camera head controlling unit 11405. The control signal includes information relating to image pickup conditions such as, for example, information that a frame rate of a picked up image is designated, information that an exposure value upon image picking up is designated and/or information that a magnification and a focal point of a picked up image are designated.

It is to be noted that the image pickup conditions such as the frame rate, exposure value, magnification or focal point may be designated by the user or may be set automatically by the control unit 11413 of the CCU 11201 on the basis of an acquired image signal. In the latter case, an auto exposure (AE) function, an auto focus (AF) function and an auto white balance (AWB) function are incorporated in the endoscope 11100.

The camera head controlling unit 11405 controls driving of the camera head 11102 on the basis of a control signal from the CCU 11201 received through the communication unit 11404.

The communication unit 11411 includes a communication apparatus for transmitting and receiving various kinds of information to and from the camera head 11102. The communication unit 11411 receives an image signal transmitted thereto from the camera head 11102 through the transmission cable 11400.

Further, the communication unit 11411 transmits a control signal for controlling driving of the camera head 11102 to the camera head 11102. The image signal and the control signal can be transmitted by electrical communication, optical communication or the like.

The image processing unit 11412 performs various image processes for an image signal in the form of RAW data transmitted thereto from the camera head 11102.

The control unit 11413 performs various kinds of control relating to image picking up of a surgical region or the like by the endoscope 11100 and display of a picked up image obtained by image picking up of the surgical region or the like. For example, the control unit 11413 creates a control signal for controlling driving of the camera head 11102.

Further, the control unit 11413 controls, on the basis of an image signal for which image processes have been performed by the image processing unit 11412, the display apparatus 11202 to display a picked up image in which the surgical region or the like is imaged. Thereupon, the control unit 11413 may recognize various objects in the picked up image using various image recognition technologies. For example, the control unit 11413 can recognize a surgical tool such as forceps, a particular living body region, bleeding, mist when the energy device 11112 is used and so forth by detecting the shape, color and so forth of edges of objects included in a picked up image. The control unit 11413 may cause, when it controls the display apparatus 11202 to display a picked up image, various kinds of surgery supporting information to be displayed in an overlapping manner with an image of the surgical region using a result of the recognition. Where surgery supporting information is displayed in an overlapping manner and presented to the surgeon 11131, the burden on the surgeon 11131 can be reduced and the surgeon 11131 can proceed with the surgery with certainty.

The transmission cable 11400 which connects the camera head 11102 and the CCU 11201 to each other is an electric signal cable ready for communication of an electric signal, an optical fiber ready for optical communication or a composite cable ready for both of electrical and optical communications.

Here, while, in the example depicted, communication is performed by wired communication using the transmission cable 11400, the communication between the camera head 11102 and the CCU 11201 may be performed by wireless communication.

An example of the endoscopic surgery system to which the technology according to an embodiment of the present disclosure can be applied is described above. The technology according to an embodiment of the present disclosure can be applied to the endoscope 11100, (the image pickup unit 11402 of) the camera head 11102, (the image processing unit 11412 of) the CCU 11201, and the like, for example, out of the configurations described above. Specifically, the configuration of the imaging apparatus 1 illustrated in FIGS. 1 and 2, the configuration of any one of the pixel regions 3 to 3H illustrated in FIGS. 3 to 11, or the imaging apparatus 1 manufactured by any one of the manufacturing methods in FIGS. 12 to 15 may be applied to the image pickup unit 10402. By applying the technology according to an embodiment of the present disclosure to the endoscope 11100, the image pickup unit 11402 of the camera head 11102, the image processing unit 11412 of the CCU 11201, and the like, for example, heat resistance of the color filter CF is enhanced, and a sharper surgical region image can be obtained, so that the surgeon can reliably confirm the surgical region.

Note that, the endoscopic surgery system is herein described as an example, but in addition to this, the technology according to an embodiment of the present disclosure may also be applied to a microscopic surgery system and the like, for example.

### Application Example to Mobile Body

The technology according to an embodiment of the present disclosure (present technology) is applicable to various products. For example, the technology according to an embodiment of the present disclosure may also be implemented as a device mounted on any type of mobile body such as an automobile, an electric automobile, a hybrid electric automobile, a motorcycle, a bicycle, a personal mobility, an airplane, a drone, a ship, and a robot.

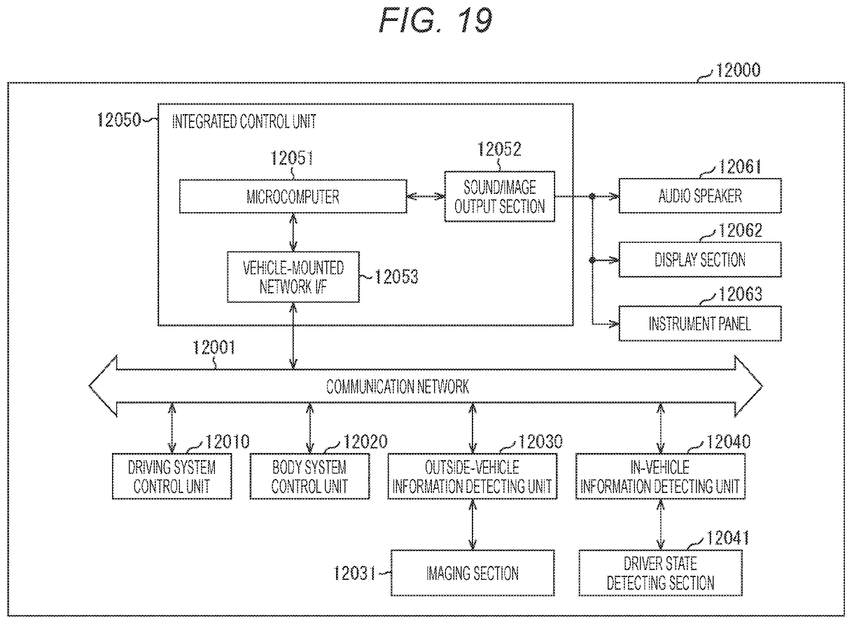

FIG. 19 is a block diagram depicting an example of schematic configuration of a vehicle control system as an example of a mobile body control system to which the technology according to an embodiment of the present disclosure can be applied.

The vehicle control system 12000 includes a plurality of electronic control units connected to each other via a communication network 12001. In the example depicted in FIG. 19, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

Furthermore, the microcomputer 12051 can output a control command to the body system control unit 12020 on the basis of the information about the outside of the vehicle obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 19, an audio speaker 12061, a display section 12062, and an instrument panel 12063 are illustrated as the output device. The display section 12062 may, for example, include at least one of an on-board display and a head-up display.

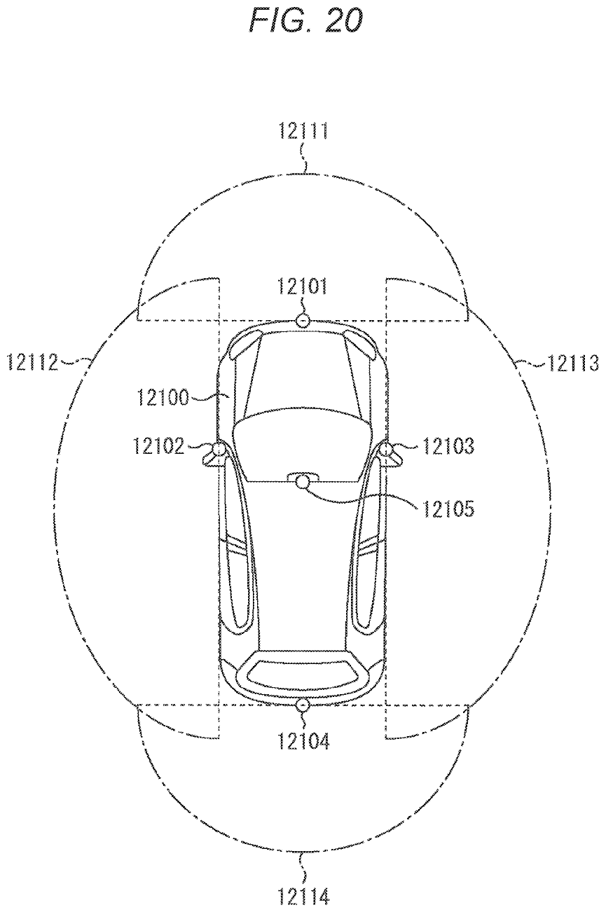

FIG. 20 is a diagram depicting an example of the installation position of the imaging section 12031.

In FIG. 20, the vehicle 12100 includes imaging sections 12101, 12102, 12103, 12104, and 12105 as the imaging section 12031.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The images of the front obtained by the imaging sections 12101 and 12105 are used mainly to detect a preceding vehicle, a pedestrian, an obstacle, a signal, a traffic sign, a lane, or the like.

Incidentally, FIG. 20 depicts an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

An example of the vehicle control system to which the technology according to an embodiment of the present disclosure may be applied is described above. The technology according to an embodiment of the present disclosure can be applied to the imaging section 12031 and the like out of the configurations described above. Specifically, the configuration of the imaging apparatus 1 illustrated in FIGS. 1 and 2, the configuration of any one of the pixel regions 3 to 3H illustrated in FIGS. 3 to 11, or the imaging apparatus 1 manufactured by any one of the manufacturing methods in FIGS. 12 to 15 may be applied to the imaging section 12031. By applying the technology according to an embodiment of the present disclosure, for example, heat resistance of the color filter CF is enhanced, and a more easily viewable taken image may be obtained, so that driver's fatigue may be reduced.

Note that, the present disclosure may also have the following configuration.

(1)

An imaging apparatus including:
a semiconductor substrate;
a color filter provided on one surface side of the semiconductor substrate; and
a first sealing material provided on the one surface side, the first sealing material that covers the color filter, in which
the first sealing material includes a material capable of transmitting light of a wavelength band set in advance and having a thermal conductivity of 0.5 W/m·K or less.

(2)

The imaging apparatus according to (1) described above, in which the first sealing material is an acrylic resin, a polyimide resin, a silicone resin, or a Bi/Si mixed inorganic material obtained by mixing bismuth and silicon.

(3)

The imaging apparatus according to (1) or (2) described above, in which a film thickness of the first sealing material is 0.1 μm or more and 2.0 μm or less.

(4)

The imaging apparatus according to any one of (1) to (3) described above, further including:
a second sealing material provided between the semiconductor substrate and the color filter, in which
the second sealing material includes a material capable of transmitting the light and having a thermal conductivity of 0.5 W/m·K or less.

(5)

The imaging apparatus according to (4) described above, in which the second sealing material is an acrylic resin, a polyimide resin, a silicone resin, or a Bi/Si mixed inorganic material obtained by mixing bismuth and silicon.

(6)

The imaging apparatus according to (4) or (5) described above, further including:
an uneven structure provided on the one surface side, in which
the uneven structure is covered with the second sealing material.

(7)

The imaging apparatus according to any one of (4) to (6) described above, further including:
a recess provided on an opposite side of a surface facing the semiconductor substrate in the second sealing material, in which
the color filter is arranged in the recess.

(8)

The imaging apparatus according to any one of (1) to (7) described above, further including:
a partition wall provided on the one surface side, in which
the color filter is surrounded by the partition wall in plan view in a normal direction of the one surface.

(9)

The imaging apparatus according to any one of (1) to (8) described above, further including: an IR filter provided on the one surface side, the IR filter that transmits or blocks infrared light.

(10)

The imaging apparatus according to any one of (1) to (9) described above, further including:
a photodiode provided on the semiconductor substrate, in which
light transmitted through the first sealing material and the color filter out of the light enters the photodiode.

(11)

A manufacturing method of an imaging apparatus, the method including steps of:
forming a color filter on one surface side of a semiconductor substrate;
forming a first sealing material on the one surface side and covering the color filter; and
performing heat treatment on an entire substrate including the semiconductor substrate, the color filter, and the first sealing material after forming the first sealing material, in which
a material capable of transmitting light of a wavelength band set in advance and having a thermal conductivity of 0.5 W/m·K or less is used as the first sealing material.

### REFERENCE SIGNS LIST

1 Imaging apparatus
2 Pixel
3, 3A, 3B, 3C, 3D, 3E, 3F, 3G, 3H Pixel region
4 Vertical driving circuit
5 Column signal processing circuit
6 Horizontal driving circuit
7 Output circuit
8 Control circuit
9 Vertical signal line
10 Horizontal signal line
11 Semiconductor substrate
11a Front surface
11b Back surface
12 Input/output terminal
25 n-type semiconductor region
26 p-type semiconductor region
27 Element separation region
28 p-type semiconductor well region
29 Gate electrode
31 Interlayer insulating film
32 Wiring
33 Multilayer wiring layer
34 Light receiving surface
42 Color filter
51 First sealing material
51b, 52b, 53b, 54b Front surface (upper surface)
52 Second sealing material
53 Third sealing material
54 Fourth sealing material
61 Wiring
62 Rig structure (uneven portion)
65 Partition wall
66 Electrode
67 Functional film
1000 Imaging apparatus
1001 Lens group
1002 Solid-state image pickup element
1003 DSP circuit
1004 Frame memory
1005 Display unit
1006 Recording unit
1007 Operating unit
1008 Power supply unit
1009 Bus line
10402 Image pickup unit
11000 Endoscopic surgery system
11100 Endoscope
11101 Lens barrel
11102 Camera head
11110 Surgical tool
11111 Pneumoperitoneum tube
11112 Energy device
11120 Supporting arm apparatus
11131 Surgeon (medical doctor)
11132 Patient
11133 Patient bed
11200 Cart
11201 Camera control unit
11202 Display apparatus
11203 Light source apparatus
11204 Inputting apparatus
11205 Treatment tool controlling apparatus
11206 Pneumoperitoneum apparatus
11207 Recorder
11208 Printer
11400 Transmission cable
11401 Lens unit
11402 Image pickup unit
11403 Driving unit
11404 Communication unit
11405 Camera head controlling unit
11411 Communication unit
11412 Image processing unit
11413 Control unit
12000 Vehicle control system
12001 Communication network
12010 Driving system control unit
12020 Body system control unit
12030 Outside-vehicle information detecting unit
12031 Imaging section
12040 In-vehicle information detecting unit
12041 Driver state detecting section
12050 Integrated control unit
12051 Microcomputer
12052 Sound/image output section
12061 Audio speaker
12062 Display section
12063 Instrument panel
12100 Vehicle
12101 to 12105 Imaging section
12111 to 12114 Imaging range
CCU11201 Imaging section
CCU11201 Camera head
CF Color filter
H1 Through-hole
H2 Recess
IRF IR filter
OCL On-chip microlens
PD Photodiode
Tr Pixel transistor

What is claimed is:

1. An imaging apparatus comprising:
a semiconductor substrate;
a color filter provided on one surface side of the semiconductor substrate; and
a first sealing material provided on the one surface side, the first sealing material that covers the color filter, wherein
the first sealing material includes a material capable of transmitting light of a wavelength band set in advance and having a thermal conductivity of 0.5 W/m·K or less.

2. The imaging apparatus according to claim 1,
wherein the first sealing material is an acrylic resin, a polyimide resin, a silicone resin, or
a Bi/Si mixed inorganic material obtained by mixing bismuth and silicon.

3. The imaging apparatus according to claim 1,
wherein a film thickness of the first sealing material is 0.1 μm or more and 2.0 μm or less.

4. The imaging apparatus according to claim 1, further comprising:
a second sealing material provided between the semiconductor substrate and the color filter, wherein
the second sealing material includes a material capable of transmitting the light and having a thermal conductivity of 0.5 W/m·K or less.

5. The imaging apparatus according to claim 4,
wherein the second sealing material is an acrylic resin, a polyimide resin, a silicone resin, or a Bi/Si mixed inorganic material obtained by mixing bismuth and silicon.

6. The imaging apparatus according to claim 4, further comprising:
an uneven structure provided on the one surface side, wherein
the uneven structure is covered with the second sealing material.

7. The imaging apparatus according to claim 4, further comprising:
a recess provided on an opposite side of a surface facing the semiconductor substrate in the second sealing material, wherein
the color filter is arranged in the recess.

8. The imaging apparatus according to claim 1, further comprising:
a partition wall provided on the one surface side, wherein
the color filter is surrounded by the partition wall in plan view in a normal direction of the one surface.

9. The imaging apparatus according to claim 1, further comprising: an IR filter provided on the one surface side, the IR filter that transmits or blocks infrared light.

10. The imaging apparatus according to claim 1, further comprising:
a photodiode provided on the semiconductor substrate, wherein
light transmitted through the first sealing material and the color filter out of the light enters the photodiode.

11. A manufacturing method of an imaging apparatus, the method comprising steps of:
forming a color filter on one surface side of a semiconductor substrate;
forming a first sealing material on the one surface side and covering the color filter; and
performing heat treatment on an entire substrate including the semiconductor substrate, the color filter, and the first sealing material after forming the first sealing material, wherein
a material capable of transmitting light of a wavelength band set in advance and having a thermal conductivity of 0.5 W/m·K or less is used as the first sealing material.
